(19) United States
(12) Patent Application Publication
(10) Pub. No.: US 2026/0081538 A1
(43) Pub. Date: Mar. 19, 2026

(54) POWER CONVERTER

(71) Applicant: DENSO CORPORATION, Kariya-city (JP)

(72) Inventors: Takenori WATANABE, Kariya-city (JP); Tomoki KOZAWA, Kariya-city (JP)

(73) Assignee: DENSO CORPORATION, Kariya-city (JP)

(21) Appl. No.: 19/397,211

(22) Filed: Nov. 21, 2025

Related U.S. Application Data
(63) Continuation of application No. PCT/JP2024/024522, filed on Jul. 8, 2024.

(30) Foreign Application Priority Data
Jul. 31, 2023 (JP) 2023-124336

(51) Int. Cl. H02M 7/537; H02M 7/00; H05K 7/20

(52) U.S. Cl. CPC H02M 7/537; H02M 7/003; H05K 7/20927

(57) ABSTRACT

An electric power converter includes a casing that defines first and second chambers separated by a partition wall. Semiconductor devices in the first chamber form a power conversion circuit and are electrically connected to a smoothing capacitor positioned in the first chamber. A noise filter is disposed in the second chamber and is electrically connected to the smoothing capacitor. The partition wall includes a cooling passage that permits flow of cooling water. A connecting busbar extends between the first and second chambers as part of a power path that links a terminal of the noise filter and terminals of the semiconductor devices. The connecting busbar includes a through portion that extends between the chambers within the casing and penetrates the partition wall.

### CROSS REFERENCE TO RELATED APPLICATIONS

The present application is a continuation application of International Patent Application No. PCT/JP2024/024522 filed on Jul. 8, 2024, which designated the U.S. and claims the benefit of priority from Japanese Patent Application No. 2023-124336 filed on Jul. 31, 2023. The entire disclosures of all of the above applications are incorporated herein by reference.

### TECHNICAL FIELD

The present disclosure relates to a power converter.

### BACKGROUND

Conventional power converters house capacitors and semiconductor modules in an upper portion of a casing, and a noise filter in a lower portion of the casing.

### SUMMARY

According to at least one embodiment, a power converter includes a casing having a first chamber and a second chamber. A partition wall separates the first chamber from the second chamber. Semiconductor devices are disposed in the first chamber and form a power conversion circuit. A smoothing capacitor is disposed in the first chamber and is electrically connected to the semiconductor devices. A noise filter is disposed in the second chamber and is electrically connected to the smoothing capacitor. A cooling passage is formed in the partition wall and allows cooling water to flow therethrough. A connecting busbar extends between the first chamber and the second chamber. The connecting busbar is included in a power path that electrically connects a terminal of the noise filter and terminals of the semiconductor devices. The connecting busbar includes a through busbar portion that extends between the first chamber and the second chamber at a location within the casing and penetrates the partition wall.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a circuit diagram of a power converter according to a first embodiment.

FIG. 2 is a cross-sectional view illustrating a configuration of the power converter.

FIG. 3 is a plan view illustrating a position of a through busbar portion in a partition wall.

FIG. 4 is a plan view illustrating a position of the through busbar portion according to another first example.

FIG. 5 is a plan view illustrating a position of the through busbar portion according to another second example.

FIG. 6 is a plan view illustrating a position of the through busbar portion according to another third example.

FIG. 7 is a perspective view illustrating a configuration of a terminal connection portion in a terminal unit.

FIG. 8 is a perspective view illustrating the terminal unit.

FIG. 9 is a perspective view illustrating a busbar incorporated in the terminal unit.

FIG. 10 is a perspective view illustrating the busbar of the terminal unit.

FIG. 11 is a partial cross-sectional view illustrating a connected state of terminals at the terminal connection portion.

FIG. 12 is a partial cross-sectional view illustrating the connected state of the terminals at the terminal connection portion.

FIG. 13 is a partial cross-sectional view illustrating a connected state of terminals according to a second embodiment.

FIG. 14 is a cross-sectional view illustrating a configuration of a power converter according to a third embodiment.

### DETAILED DESCRIPTION

To begin with, examples of relevant techniques will be described.

A power converter according to a comparative example houses a capacitor and a semiconductor module in an upper portion of a casing, and a noise filter in a lower portion of the casing. The upper portion and the lower portion are partitioned by a wall provided inside the casing. Three busbars penetrate through the wall.

Since the three busbars penetrate through the wall, it is necessary to secure space for the three busbars to pass through the wall. Therefore, when viewing an interior of the casing in a downward plan view, there is an issue in that an area required for installing electrical components becomes larger.

In contrast to the comparative example, according to a power converter of the present disclosure, an area for accommodating electrical components can be reduced when an inside of a casing is viewed in plan.

According to one aspect of the present disclosure, a power converter includes a casing having a first chamber and a second chamber. A partition wall separates the first chamber from the second chamber. Semiconductor devices are disposed in the first chamber and form a power conversion circuit. A smoothing capacitor is disposed in the first chamber and is electrically connected to the semiconductor devices. A noise filter is disposed in the second chamber and is electrically connected to the smoothing capacitor. A cooling passage is formed in the partition wall and allows cooling water to flow therethrough. A connecting busbar extends between the first chamber and the second chamber. The connecting busbar is included in a power path that electrically connects a terminal of the noise filter and terminals of the semiconductor devices. The connecting busbar includes a through busbar portion that extends between the first chamber and the second chamber at a location within the casing and penetrates the partition wall.

According to this configuration, since the busbar penetrates the partition wall at a single location within the casing, a space for arranging electrical components such as the noise filter and the smoothing capacitor can be made compact. As a result, it becomes possible to reduce the internal dimensions of the casing when the partition wall is viewed in plan. Therefore, the power converter can reduce an area required for accommodating electrical components within the casing when viewed in plan with respect to the partition wall. Furthermore, since only the through busbar portion penetrates the partition wall and the other sections do not, it is possible to arrange the busbar close to or along the cooling passage over a wide area. As a result, it is possible to reduce portions of the busbar that are difficult to cool with cooling water, thereby improving the ability to cool the busbar.

Hereinafter, embodiments for implementing the present disclosure are described referring to drawings. In each embodiment, the same reference numerals may be given to parts corresponding to matters described in a preceding embodiment, and overlapping explanations may be omitted. When only a part of a configuration is described in an embodiment, the other preceding embodiments can be applied to the other parts of the configuration. It may be possible not only to combine parts which are explicitly described in the embodiments to be able to be combined specifically, but also to partially combine the embodiments without such explicit description unless there is a problem with the combination.

### First Embodiment

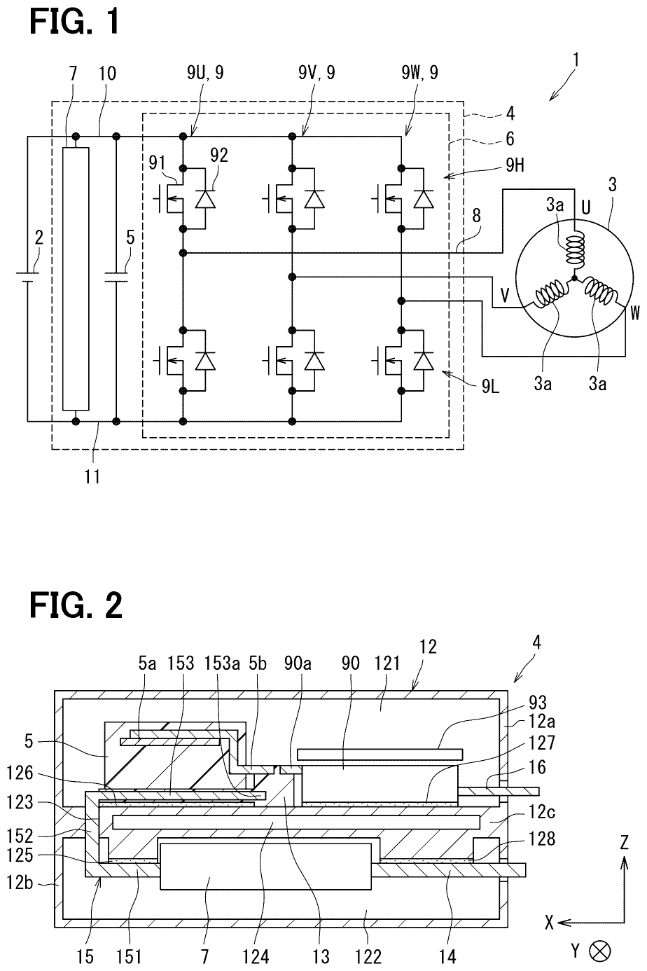

A first embodiment showing an example of a power converter will be described with reference to FIGS. 1 to 12. Examples of applications of the power converter are as follows. The power converter can be applied to onboard power converters installed in vehicles such as electric vehicles, hybrid vehicles, and plug-in hybrid vehicles. The power converter can also be installed in aircraft such as electric vertical take-off and landing vehicles (eVTOLs) and drones, as well as in ships, construction machinery, and agricultural machinery. The following describes an example in which the power converter is applied to a vehicle.

As shown in FIG. 1, a drive system 1 of the vehicle includes a DC power supply 2, a motor generator 3, and a power converter 4. The DC power supply 2 is a direct-current voltage source including a chargeable and dischargeable secondary battery. The secondary battery may be, for example, a lithium-ion battery, and a nickel-metal hydride battery. The motor generator 3 is, for example, a rotary electric machine of a three-phase AC type. The motor generator 3 functions as a vehicle driving power source, that is, an electric motor. The motor generator 3 functions also as a generator during regeneration. The power converter 4 performs power conversion between the DC power supply 2 and the motor generator 3.

The power converter 4 has a power conversion circuit. As shown in FIG. 1, the power converter 4 includes a smoothing capacitor 5, an inverter 6 serving as a power conversion circuit, and a noise filter 7. The smoothing capacitor 5 primarily functions to smooth the DC voltage supplied from the DC power supply 2. The smoothing capacitor 5 is connected between a P-line 10 which is a power line on a high potential side and an N-line 11 which is a power line on a low potential side.

The smoothing capacitor 5 is connected to the DC power supply 2 in parallel. The P line 10 is connected to a positive terminal of the DC power supply 2. The N line 11 is connected to a negative terminal of the DC power supply 2. A positive terminal of the smoothing capacitor 5 is connected to the P line 10 between the DC power supply 2 and the inverter 6. A negative terminal of the smoothing capacitor 5 is connected to the N line 11 between the DC power supply 2 and the inverter 6. The P line 10 includes P busbars, each of which connects electrical components to one another. The N line 11 includes N busbars, each of which connects electrical components to one another.

The inverter 6 is a DC-AC conversion circuit. The inverter 6 converts the DC voltage into a three-phase AC voltage in accordance with switching control by a control circuit provided on a control circuit board 93, and outputs it to the motor generator 3. By this operation, the motor generator 3 is driven so as to generate a predetermined torque. During regenerative braking of the vehicle, the inverter 6 converts the three-phase AC voltage generated by the motor generator 3, which receives rotational force from the wheels, into DC voltage in accordance with switching control by the control circuit. The converted DC power is output to the P line 10. In this manner, the inverter 6 performs bidirectional power conversion between the DC power supply 2 and the motor generator 3.

The noise filter 7 is connected to each of the P line 10 and the N line 11. The noise filter 7 is connected in parallel with the DC power supply 2. A positive terminal of the noise filter 7 is connected to the P line 10 between the DC power supply 2 and the smoothing capacitor 5. A negative terminal of the noise filter 7 is connected to the N line 11 between the DC power supply 2 and the smoothing capacitor 5. The noise filter 7 removes noise that is input to or output from the P line 10 and the N line 11. The noise filter 7 may be configured to include a capacitor. The capacitor included in the noise filter 7 has a smaller capacitance than the smoothing capacitor 5.

The inverter 6 has upper-lower arm circuits 9 corresponding to each of the three phases. The upper-lower arm circuits 9 may also be referred to as legs. One of the upper-lower arm circuits 9 includes an upper arm 9H and a lower arm 9L. The upper arm 9H and the lower arm 9L are connected in series between the P line 10 and the N line 11, with the upper arm 9H on the P line 10 side and the lower arm 9L on the N line 11 side.

A connection point between the upper arm 9H and the lower arm 9L is connected to a winding 3a of a corresponding phase in the motor generator 3 via an output line 8. Of the upper-lower arm circuits 9, an upper-lower arm circuit 9U for a U phase is connected to a U-phase winding 3a via the corresponding output line 8. An upper-lower arm circuit 9V for a V phase is connected to a V-phase winding 3a via the corresponding output line 8. An upper-lower arm circuit 9W for a W phase is connected to a W-phase winding 3a via the corresponding output line 8. At least a portion of the output line 8 is constituted by a conductive member, such as a busbar, for example.

The inverter 6 has six arms. Each arm is provided with a switching element. The number of switching elements constituting each arm is not particularly limited. It may be a single element or elements. In a case of elements, switching elements connected in parallel to each other are driven on and off at the same timing by a common gate drive signal.

In this specification, an n-channel type metal oxide semiconductor field effect transistor (MOSFET) 91 is employed as the switching element constituting each arm. In the upper arm 9H, a drain of the MOSFET 91 is connected to the P line 10. In the lower arm 9L, a source of the MOSFET 91 is connected to the N line 11. The source of the MOSFET 91 in the upper arm 9H and the drain of the MOSFET 91 in the lower arm 9L are interconnected.

A freewheeling diode 92 is connected in anti-parallel to each of MOSFETs 91. The diode 92 may be a parasitic diode of the MOSFET 91, or it may be provided separately from the parasitic diode. An anode of the diode 92 is connected to the source of the corresponding MOSFET 91. A cathode of the diode 92 is connected to the drain.

The switching element is not limited to the MOSFET 91. An integrated gate bipolar transistor (IGBT) may be used as the switching element. In a case of an IGBT as well, a freewheeling diode is connected in reverse parallel.

As shown in FIG. 2, the power converter 4 includes semiconductor devices 90, the control circuit board 93, the smoothing capacitor 5, and the noise filter 7, which are provided inside a casing 12. A semiconductor device 90 is one of the semiconductor devices. The semiconductor device provides at least one arm of the power conversion circuit. The semiconductor device 90 provides the upper-lower arm circuits 9 for one phase. The semiconductor devices 90 are connected in parallel to provide the power conversion circuit. The semiconductor devices 90 may also be referred to as semiconductor modules. In the following, three mutually orthogonal directions will be referred to as an X-direction, a Y-direction, and a Z-direction. The X-direction and the Y-direction indicate directions along a horizontal plane. The Z-direction corresponds to a vertical direction.

The casing 12 is a container that houses electrical components such as the smoothing capacitor 5, the semiconductor device 90, the control circuit board 93, and the noise filter 7. The casing 12 is formed by combining case members. The casing 12 is made of aluminum or an alloy. Each component is formed, for example, by aluminum die casting. An interior of the casing 12 is largely divided into a first chamber 121 and a second chamber 122 by a partition wall 12c. The first chamber 121 is a space partitioned above the partition wall 12c. The second chamber 122 is a space partitioned below the partition wall 12c. The partition wall 12c is formed from a material that enables good heat transfer to components in contact with the partition wall 12c.

In the first chamber 121, components such as the smoothing capacitor 5, the control circuit board 93, and the semiconductor devices 90 are provided. In the second chamber 122, components such as the noise filter 7 are provided. An input line connecting the DC power supply 2 and the noise filter 7 is inserted through a side wall 12a of the casing 12. The side wall 12a is a wall portion that is adjacent to a ceiling wall and a bottom wall of the casing 12, and connects the ceiling wall and the bottom wall. The side wall 12a forms a side surface extending in an up-down direction, and forms the side surface parallel to the Y-direction and the Z-direction. At a position facing the side wall 12a, a side wall 12b of the casing 12 is provided.

The input line is configured to include a part of the P line 10 and a part of the N line 11. The input line includes two input busbars 14. The input line is provided in the second chamber 122. The input line and the side wall 12a are insulated from each other by an insulating component. The insulating component is, for example, an input connector. Inside the input connector, a terminal connected to a tip of an input busbar 14 is provided. A terminal of a wire harness extending from the DC power supply 2 is connected to the terminal inside the input connector. As a result, each of the P line 10 and the N line 11 is electrically connected to the DC power supply 2.

An output line 8 that connects the motor generator 3 and the semiconductor device 90 is inserted through the side wall 12a of the casing 12. The output line 8 includes three output busbars 16. The output busbars 16 are provided in the first chamber 121. The output line 8 and the side wall 12a are insulated from each other by insulating components. The insulating component is, for example, an output connector. Inside the output connector, a terminal connected to a tip of the output busbar 16 is provided. A terminal of a wire harness extending from the motor generator 3 is connected to the terminal inside the output connector. As a result, each phase of the upper-lower arm circuits 9 is electrically connected to the winding 3a of the motor generator 3.

The smoothing capacitor 5 includes a capacitor element, a sealing member, an electrode 5a connected to the capacitor element, and a terminal 5b. The sealing member is filled into a housing portion of the capacitor element to seal the capacitor element. The sealing member seals the capacitor element within the accommodation space. The sealing member forms an outer shell of the smoothing capacitor 5. The outer shell of the smoothing capacitor 5, except for the terminal 5b and the like, has a rectangular parallelepiped shape. The sealing member is made of a thermosetting resin such as an epoxy resin. The sealing member is an insulating material that is filled in gaps between the capacitor element and the electrode 5a, and between the capacitor element and the housing portion. With this configuration, the sealing member seals the capacitor element, the electrode 5a, and the like. One end of the terminal 5b is connected to the electrode 5a inside the smoothing capacitor 5, and the other end protrudes from the sealing member into the first chamber 121. In the first chamber 121, the terminal 5b is connected to the P line 10 and the N line 11 via the terminal connection portion of the terminal unit 13.

The smoothing capacitor 5 is installed in the first chamber 121 in an orientation in which a direction with the smallest external length (up-down direction) is positioned vertically. With this configuration, it is possible to reduce the length occupied by the smoothing capacitor 5 in the up-down direction within the first chamber 121. Further, the smoothing capacitor 5 is installed in the first chamber 121 in an orientation in which its largest external surface is aligned along the partition wall 12c.

Except for a terminal 90a protruding from the sealing member, the semiconductor device 90 has a flat body-shaped outer profile formed by the sealing member. The semiconductor device 90 is installed in the first chamber 121 in such a way that its thickness direction, which has the smallest edge dimension, is aligned with the vertical direction. The control circuit board 93 is installed above the semiconductor device 90 with the thickness direction of a substrate aligned along the vertical direction. With this configuration, it is possible to reduce the vertical length occupied by the semiconductor device 90 and the control circuit board 93 in the first chamber 121. In addition, the semiconductor device 90 is installed in the first chamber 121 in an orientation in which the largest surface of its flat body-shaped outer profile is aligned along the partition wall 12c.

On one side of the flat body shape, a terminal 90a forming a collector terminal and an emitter terminal projects outward. The terminal 90a projects toward the smoothing capacitor 5 and is connected to the P line 10 and the N line 11 via the terminal connection portion of the terminal unit 13. On the other side of the flat body shape, an intermediate terminal projects outward. The intermediate terminal is connected to the output line 8. A gate terminal of the semiconductor device 90 is connected to the control circuit board 93. The control circuit board 93 forms a control circuit on which electronic components such as arithmetic elements for controlling the operation of the MOSFET 91 are mounted.

As shown in FIG. 2, the power converter 4 is provided with a power path that connects a terminal of the noise filter 7 and the terminal 90a of the semiconductor device. This power path is formed to include a connecting busbar 15. The connecting busbar 15 extends across the first chamber 121 and the second chamber 122, and is provided so as to run along the partition wall 12c. The connecting busbar 15 includes a first busbar portion 151 mainly located in the second chamber 122, a second busbar portion mainly located in the first chamber 121, and a through busbar portion 152. The relay busbar 153 shown in FIG. 2 corresponds to the second busbar portion. The relay busbar 153 is formed to include a P-side busbar included in the high-potential P line 10 and an N-side busbar included in the low-potential N line 11.

The first busbar portion 151 extends in the second chamber 122 along a cooling passage 124 toward the through busbar portion 152. The first busbar portion 151 includes a busbar that forms part of the P line 10 and a busbar that forms part of the N line 11. The first busbar portion 151 is in thermally transferable contact with the partition wall 12c via an insulating member 125. The insulating member 125 is a sheet-like member, grease, gel-like object, gap filler, resin mold covering the busbar, or the like, formed from an insulating material. The first busbar portion 151 is provided so as to extend along the cooling passage 124. The first busbar portion 151 is provided so as to overlap the cooling passage 124 in plan view.

The relay busbar 153 extends along the cooling passage 124 in the first chamber 121, from a side of the through busbar portion 152 toward the semiconductor device 90. The relay busbar 153 is provided so as to extend along the cooling passage 124. The relay busbar 153 is provided so as to overlap the cooling passage 124 in plan view. The relay busbar 153 includes a portion that is disposed below the smoothing capacitor 5 and a portion that is not disposed below the smoothing capacitor 5. The portion disposed below the smoothing capacitor 5 makes use of a space below the smoothing capacitor 5 to cool the busbar, while also enabling a busbar arrangement that does not spread significantly outward.

The relay busbar 153 includes a busbar that is part of the P line 10 and a busbar that is part of the N line 11. The relay busbar 153 is covered with a sealing member having insulating property. A portion of the relay busbar 153 that is covered by the sealing member is in contact with the partition wall 12c via a heat-conductive member 126. The heat-conductive member 126 is a sheet-like member, grease, gel-like object, gap filler, or the like, formed from a material having high thermal conductivity.

A through-hole 123, which connects the first chamber 121 and the second chamber 122, is formed in the partition wall 12c. The through busbar portion 152 is a part of the connecting busbar 15 that is located between the first busbar portion 151 and the relay busbar 153, and passes vertically through the through-hole 123 of the partition wall 12c. Accordingly, the connecting busbar 15 may be configured with three busbars, namely the first busbar portion 151, the through busbar portion 152, and the relay busbar 153, joined together, or it may be configured with two busbars joined together. In a case where two busbars are joined together, a portion corresponding to the through busbar portion 152 may be, for example, a part of the first busbar portion 151 or a part of the relay busbar 153. The through busbar portion 152 includes a busbar that is a part of the P line 10 and a busbar that is a part of the N line 11. The through busbar portion 152 passes through the partition wall 12c at a location adjacent to the cooling passage 124.

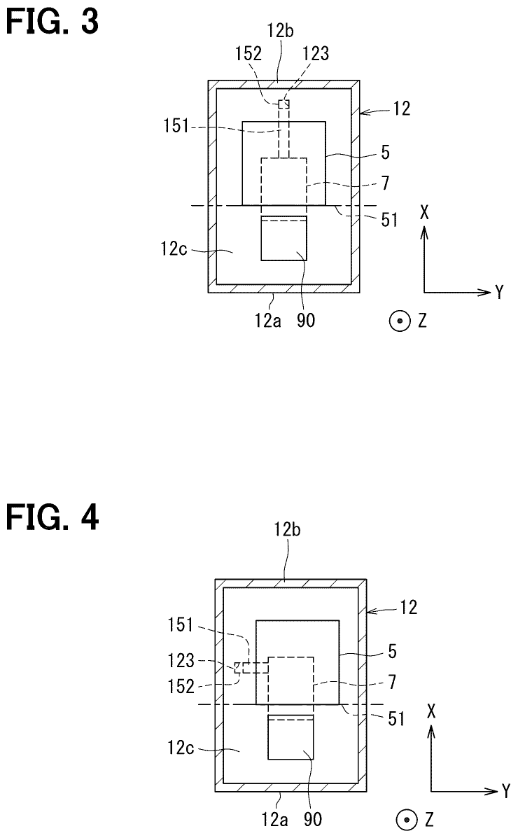

FIG. 3 shows a position of the through busbar portion 152 inside the casing 12 in a plan view. As shown in FIGS. 3 to 6, the through busbar portion 152 may be positioned in an area on an opposite side, away from the semiconductor device 90, relative to a side surface portion 51 of the outer shell of the smoothing capacitor 5. The side surface portion 51 is a part of the side surface of the smoothing capacitor 5 that is located closest to the semiconductor device 90.

The through busbar portion 152 is provided, in plan view, within a range located closer to the side wall 12b than an extension line of the side surface portion 51 indicated by a two-dot chain line in FIG. 3. This range is an area, in the plan view of FIG. 3, between the extension line of the side surface portion 51 and the inner surface of the side wall 12b. The through busbar portion 152 shown in FIG. 3 is provided outside an external surface portion of the smoothing capacitor 5, which is located on a side opposite to the semiconductor device 90. This external surface portion is positioned, in plan view, so as to face the side wall 12b of the housing that is located on the side opposite to the semiconductor device 90. In plan view, the through busbar portion 152 is positioned between this external surface portion and the side wall 12b. The noise filter 7 and the smoothing capacitor 5 are installed so as to overlap in a direction perpendicular to the partition wall 12c in plan view. The smoothing capacitor 5 and the semiconductor device 90 are installed so as not to overlap in the direction perpendicular to the partition wall 12c in plan view.

Further, other examples regarding the position of the through busbar portion 152 will be described with reference to FIGS. 4 to 6. FIG. 4 shows another first example. The through busbar portion 152 shown in FIG. 4 is located in an area on the opposite side, farther from the semiconductor device 90 than the side surface portion 51 of the outer shell of the smoothing capacitor 5. The through busbar portion 152 shown in FIG. 4 is provided outside the smoothing capacitor in a direction perpendicular to a direction in which the semiconductor device and the smoothing capacitor are arranged in plan view. Accordingly, as shown in FIG. 4, it is possible to reduce the size of the power converter 4 in the direction in which the semiconductor device and the smoothing capacitor are arranged side by side in plan view.

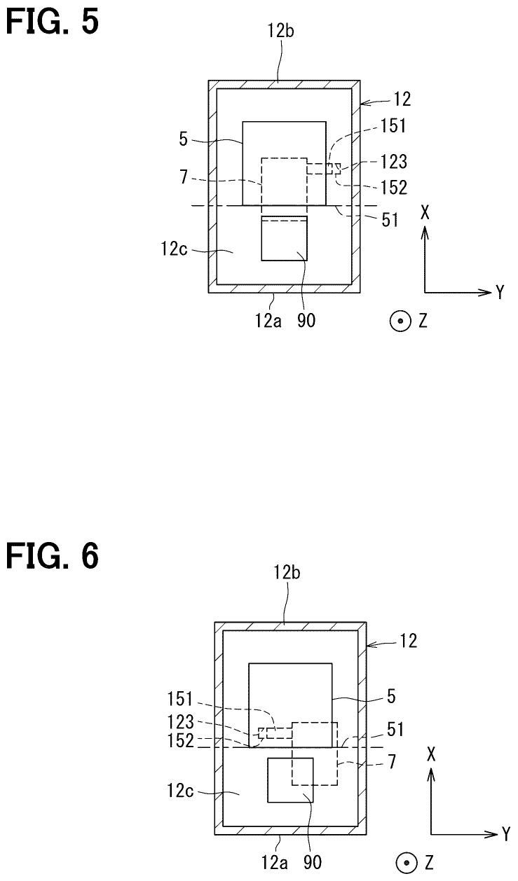

FIG. 5 shows another second example. The through busbar portion 152 shown in FIG. 5 is located in an area on the opposite side, farther from the semiconductor device 90 than the side surface portion 51 of the outer shell of the smoothing capacitor 5. The through busbar portion 152 shown in FIG. 5 is provided outside the smoothing capacitor in a direction perpendicular to a direction in which the semiconductor device and the smoothing capacitor are arranged in plan view. The through busbar portion 152 shown in FIG. 5 is provided outside the smoothing capacitor on the side opposite to the through busbar portion 152 shown in FIG. 4. Accordingly, as shown in FIG. 5, it is possible to reduce the size of the power converter 4 in the direction in which the semiconductor device and the smoothing capacitor are arranged side by side in plan view.

FIG. 6 shows another third embodiment. The through busbar portion 152 shown in FIG. 6 is located in an area on the opposite side, farther from the semiconductor device 90 than the side surface portion 51 of the outer shell of the smoothing capacitor 5. The through busbar portion 152 shown in FIG. 6 is provided in a region that overlaps the smoothing capacitor in plan view. Accordingly, as shown in FIG. 6, it is possible to reduce the size of the power converter 4 both in the direction in which the semiconductor device and the smoothing capacitor are arranged side by side in plan view, and in a direction orthogonal to this direction.

Inside the partition wall 12c, the cooling passage 124 through which cooling water circulates is provided. The cooling passage 124 is formed so as to follow along the partition wall 12c. The cooling passage 124 is a passage that is arranged throughout the entire partition wall 12c. The cooling passage 124 is a passage arranged to meander extensively along the partition wall 12c. The cooling water flowing through the cooling passage 124 serves to cool electrical components and busbars arranged above or below the partition wall 12c. As the cooling water, it is also possible to use a phase-change refrigerant such as water or ammonia, or a non-phase-change refrigerant such as an ethylene glycol-based fluid. The cooling passage 124 is provided so as to overlap with at least a part of the smoothing capacitor 5, the semiconductor device 90, and the noise filter 7 in plan view. It is preferable that the cooling passage 124 is provided so as to overlap entirely with the smoothing capacitor 5, the semiconductor device 90, and the noise filter 7 in plan view. A line-of-sight direction in plan view described in this specification is perpendicular to the partition wall 12c.

The input busbar 14 is in thermally transferable contact with the partition wall 12c via an insulating member 128. The insulating member 128 is a sheet-shaped member, grease, gel-like object, gap filler, resin mold covering the busbar, or the like, formed from an insulating material. It is preferable that the insulating member 128 is made of a material that is both electrically insulating and highly thermally conductive. The input busbar 14 is provided along the cooling passage 124. The input busbar 14 is provided so as to overlap the cooling passage 124 in plan view. The input busbar 14 extends from the side wall 12a to the outside of the casing 12 at a position lower than the output busbar 16.

The output busbar 16 is in thermally transferable contact with the partition wall 12c via an insulating member 127. The insulating member 127 is a sheet-like member, grease, gel-like object, gap filler, resin mold covering the busbar, or the like, formed from an insulating material. The output busbar 16 is provided so as to follow along the cooling passage 124. At least a part of the output busbar 16 is provided so as to overlap with the cooling passage 124 in a plan view. For the aforementioned insulating member, for example, a ceramic plate or a resin sheet can be used. Furthermore, a silicone gel or the like may be used for the insulating member to enhance thermal conductivity.

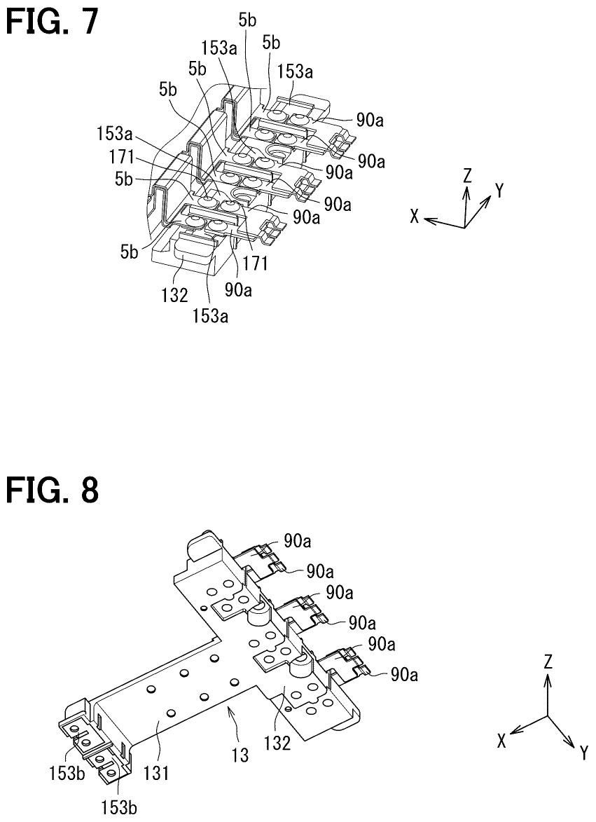

With reference to FIGS. 7 to 12, a configuration of the terminal unit 13 will be described. The power converter 4 has the terminal unit 13, which includes the intermediate busbar 153, resin molds 131, 132 that house the intermediate busbar 153. As shown in FIG. 8, the resin molds 131 and 132 are resin portions that cover parts of the intermediate busbar 153 except for a first terminal 153a and a second terminal 153b. The resin molds 131 and 132 are formed from insulating material that insulates the intermediate busbar 153 from surrounding conductive members. A pair of intermediate busbars 153 can be integrally installed with the resin portions of the terminal unit 13 by insert molding during the molding of the terminal unit 13.

The first terminal 153a is a busbar terminal provided at one end of the intermediate busbar 153. The second terminal 153b is provided at the other end of the intermediate busbar 153. The second terminal 153b is to be connected to one end of a busbar corresponding to the through busbar portion 152. The other end of the busbar corresponding to the through busbar portion 152 is to be connected to the end of the first busbar portion 151. It should be noted that in FIG. 8, in addition to the terminal unit 13, a terminal 90a of the semiconductor device connected to the first terminal 153a is also illustrated.

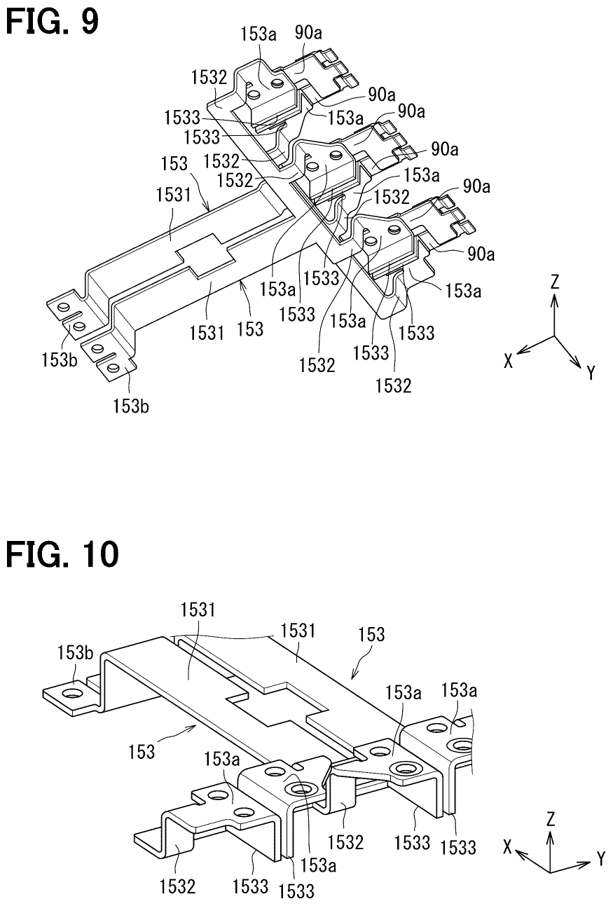

As shown in FIG. 9, the terminal unit 13 has two intermediate busbars 153. The two intermediate busbars 153 are insulated from each other by the resin molds 131 and 132. This pair of intermediate busbars 153 includes a P-side busbar that forms part of the high-potential P line 10 and an N-side busbar that forms part of the low-potential N line 11. Each intermediate busbar 153 is provided with a main section 1531 that extends in the X-direction, and branch sections 1532 branching from the main section 1531. The branch sections 1532 are arranged side by side in the Y-direction. An end portion of the main section 1531 corresponds to the second terminal 153b. The intermediate busbar 153 of the present embodiment has three branch sections 1532, each of which is connected to the upper-lower arm circuits 9 of the three phases. An end portion of the branch section 1532 corresponds to the first terminal 153a. As shown in FIG. 7, the six branch sections 1532 are arranged side by side in the Y-direction.

The resin mold 131 covers two main sections 1531, insulating a pair of main sections 1531 from each other and from surrounding conductive members. The resin mold 132 covers the three branch sections 1532, insulating the three branch sections 1532 from each other and from surrounding conductive members. The resin molds 131 and 132 are formed so as to contact the partition wall 12c via the heat-conductive member 126 in an installed state of the terminal unit 13.

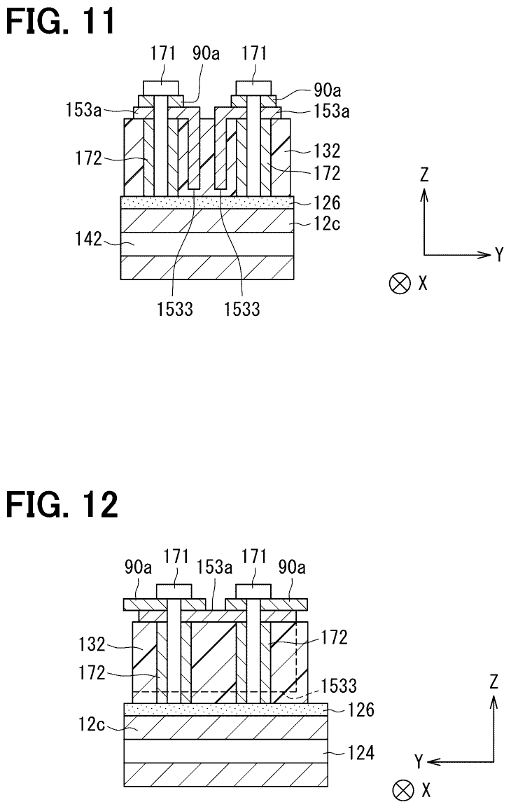

As shown in FIG. 7, each of the terminal 90a of the semiconductor device and the terminal 5b of the smoothing capacitor is fixed to the relay busbar 153 in a state of surface contact with the first terminal 153a. As shown in FIGS. 11 and 12, the terminal 90a of the semiconductor device is fastened and fixed to the first terminal 153a by a bolt 171 in a state of surface contact. As shown in FIG. 7, the terminal 5b of the smoothing capacitor is similarly fastened and fixed to the first terminal 153a in a state of surface contact by the bolt 171 and a nut 172. In other words, the terminal 90a shown in FIGS. 11 and 12 can be replaced with the terminal 5b of the smoothing capacitor.

By screwing a female thread portion formed on a radially inner surface of the nut 172 onto a male thread portion of the bolt 171, the terminal 90a is clamped between a head of the bolt 171 and the first terminal 153a. The nut 172 is fixed to the resin mold 132 in a state of being covered with a resin material. The nut 172 is provided on the terminal unit 13 in a state of being in contact with the heat-conductive member 126.

With this configuration, a heat transfer path can be formed in which heat is sequentially transferred from the terminal 90a, the bolt 171, the nut 172, the heat-conductive member 126, the partition wall 12c, and then to the cooling water. It is preferable that the nut 172 is in contact with the first terminal 153a at an end opposite to a portion where it contacts the heat-conductive member 126. With this configuration, in addition to the above-mentioned heat transfer path, a heat transfer path can also be formed in which heat is sequentially transferred from the terminal 90a, the nut 172, the heat-conductive member 126, the partition wall 12c, and then to the cooling water. By forming these heat transfer paths, heat dissipation capability of the terminal 5b of the smoothing capacitor, the terminal 90a of the semiconductor device, and the busbar can be improved. The nut 172 can be integrally installed with the resin mold 132 by insert molding during the molding of the terminal unit 13.

Each of the P-side busbar and the N-side busbar of the intermediate busbar 153 is provided with an extension portion 1533 that bends from the first terminal 153a and is embedded within the resin mold 132. As shown in FIGS. 10 to 12, the extension portion 1533 of the P-side busbar and the extension portion 1533 of the N-side busbar extend toward the partition wall in mutually opposing orientations. This pair of extension portions 1533 may be configured so that their tips are in contact with the heat-conductive member 126, or so that they are slightly separated from the heat-conductive member 126. According to the extension portion 1533, a heat transfer path can be formed from the first terminal 153a of the intermediate busbar to the heat-conductive member 126 via the extension portion, enabling heat dissipation. In this way, by providing multiple heat transfer paths including the heat transfer path via the nut 172, it is possible to improve the heat dissipation performance from the first terminal 153a. Furthermore, according to the configuration of the extension portion 1533, the extension portions of the P-side busbar and the N-side busbar can be formed so that mutually opposite electric current flow through the respective extension portions. As a result, it is possible to reduce the inductance with respect to the P-side busbar and the N-side busbar.

Actions and effects brought about by the power converter 4 will be described. The power converter 4 is provided with the partition wall 12c that divides the interior of the casing 12 into the first chamber 121 and the second chamber 122. The semiconductor devices 90 and the smoothing capacitor 5 are housed in the first chamber 121. The noise filter 7 is housed in the second chamber 122. The cooling passage 124, through which the cooling water flows, is formed in the partition wall 12c. The power converter 4 has the connecting busbar 15, which is included in the power path that connects the terminal of the noise filter and the terminal 90a of the semiconductor device. The connecting busbar 15 has the through busbar portion 152 that extends across both the first chamber 121 and the second chamber 122 at one location inside the casing 12 and penetrates the partition wall 12c. The through busbar portion 152 is in contact with the partition wall 12c via the insulating member in a manner that allows heat transfer. This insulating member is a sheet-like member, grease, gel-like object, gap filler, resin mold covering the busbar, or the like, formed from an insulating material.

In the power converter 4, the busbar penetrates the partition wall 12c at only one location inside the casing 12. Therefore, an area required for arranging electrical components such as the noise filter 7 and the smoothing capacitor 5 can be made compact. In other words, a projected area of the electrical components when projected onto the partition wall can be made compact. As a result, it becomes possible to reduce the internal dimensions of the casing 12 when the partition wall 12c is viewed in plan. Therefore, in the power converter 4, when the inside of the housing is viewed in plan, the area for accommodating electrical components can be minimized. Furthermore, since only the through busbar portion penetrates the partition wall 12c and the other sections do not, it is possible to arrange the busbar close to or along the cooling passage over a wide area. Therefore, it is possible to reduce portions of the busbar that are difficult to cool with cooling water, thereby improving the ability to cool the busbar.

The through busbar portion 152 penetrates the partition wall in an area farther from the semiconductor device than the side surface portion 51 of the smoothing capacitor that is closest to the semiconductor device, when viewed in plan. With this configuration, the smoothing capacitor and the semiconductor device can be installed closer together in a plan view. Therefore, the busbar connecting the smoothing capacitor and the semiconductor device can be made shorter, which makes it possible to reduce the inductance.

The through busbar portion 152 penetrates the partition wall at a position further outward than the external surface portion of the smoothing capacitor located on the opposite side of the semiconductor device, when viewed in plan. According to this, as shown in FIG. 3, it is possible to reduce the size of the power converter 4 in the direction orthogonal to the direction in which the semiconductor device and the smoothing capacitor are aligned in plan view.

As shown in FIG. 2, the smoothing capacitor 5 is positioned closer to the semiconductor device 90 than the through busbar portion 152. According to this configuration, the structure and size of the cooling passage 124 can be made compact.

As shown in FIG. 2, the noise filter 7 is positioned closer to the semiconductor device 90 than the smoothing capacitor 5 with respect to the through busbar portion 152. According to this configuration, it is possible to adopt a structure in which the relay busbar 153 extends along the cooling passage 124 for a longer distance, thereby improving the ability to cool the relay busbar 153.

The connecting busbar 15 further includes the first busbar portion 151 that extends toward the through busbar portion along the cooling passage in the second chamber, and the second busbar portion that extends along the cooling passage from the side of the through busbar portion toward the semiconductor device in the first chamber. The through busbar portion 152 penetrates the partition wall 12c at a position adjacent to the cooling passage 124. According to this configuration, the first busbar portion and the second busbar portion are arranged to extend along the flow of the cooling water. Therefore, for the first busbar portion and the second busbar portion, it is possible to increase an amount of heat dissipation over a wide range in a longitudinal direction. Furthermore, for the through busbar portion 152, since the cooling water can be brought into close proximity, the heat dissipation effect of the busbar at the portion penetrating the partition wall 12c can be enhanced. Accordingly, for the busbar extending from the noise filter 7, penetrating the partition wall 12c, to the semiconductor device 90 side, it is possible to set a wide range of sections that can be cooled.

The first busbar portion 151 is provided in contact with the partition wall 12c via an insulator, between the smoothing capacitor 5 and the cooling passage 124. According to this configuration, it is possible to realize an effective heat transfer path in which the heat generated by the first busbar portion 151 is transferred to the partition wall 12c and absorbed by the cooling water. Accordingly, it is possible to provide the power converter 4 in which the cooling effect of the first busbar portion 151 can be achieved.

The first chamber 121 is positioned above the second chamber 122. The through busbar portion 152 extends vertically across both the first chamber and the second chamber at a location inside the casing 12, penetrating the partition wall 12c. Accordingly, by adopting a configuration in which the chambers inside the casing have a two-layer vertical structure, it is possible to provide the power converter that achieves a reduction in the lateral length of the casing.

The power converter 4 includes the input busbar 14 for the input line connecting the DC power supply 2 and the noise filter 7, and the output busbar 16 for the output line connected to the semiconductor device. The input busbar and the output busbar extend to the outside of the casing 12 from the same side wall 12a of the casing. According to this configuration, a power input section and a power output section of the power converter can be accessed from the same side of the casing. Therefore, the installation space occupied by the power converter 4, the DC power supply 2, and the output equipment can be made compact.

### Second Embodiment

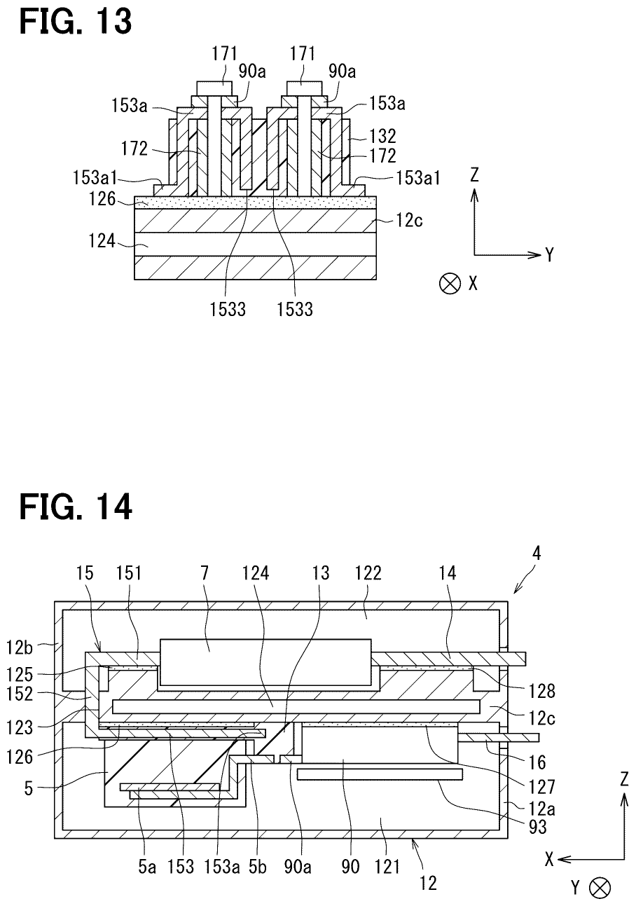

A second embodiment will be described with reference to FIG. 13. The power converter of the second embodiment differs from the first embodiment in that it has a heat transfer path from the first terminal 153a to a contact heat dissipation section 153a1. Configurations, actions, and effects not specifically described in the second embodiment are the same as those in the first embodiment, and points different from the first embodiment will be described below.

Each of the P-side busbar and N-side busbar of the relay busbar 153 is provided with the contact heat dissipation section 153a1 that extends from the first terminal 153a toward a bent partition wall 12c. The contact heat dissipation section 153a1 is installed so as to be in contact with the heat-conductive member 126. The heat-conductive member 126 of the second embodiment is a sheet-like member, grease, gel-like object, gap filler, or the like, formed from a material that has high thermal conductivity and is also electrically insulating. A portion extending from the first terminal 153a toward the bent partition wall 12c is covered by the resin mold 132. A portion that comes into contact with the heat-conductive member 126 is a part that protrudes from the resin mold 132.

The P-side busbar and N-side busbar of the second embodiment each have the contact heat dissipation section 153a1 that comes into contact with the partition wall via an insulator. According to this configuration, it is possible to form a heat transfer path that dissipates heat from the first terminal 153a to the heat-conductive member 126 via the contact heat dissipation section 153a1. In the second embodiment, formation of multiple heat transfer paths, including the heat transfer path via the extension portion 1533, makes it possible to improve the heat dissipation performance from the first terminal 153a.

### Third Embodiment

A third embodiment will be described with reference to FIG. 14. A power converter of the third embodiment differs from the first embodiment in that a first chamber 121 is provided below the second chamber 122. In the following description, explanations for configurations, operations and effects of the seventh embodiment that are the same as those of the above-described embodiments will be omitted. That is, features of the third embodiment different from those of the above-described embodiments will be described hereafter.

An input busbar 14 extends from the side wall 12a to the outside of the casing 12 at a position higher than an output busbar 16. The semiconductor devices 90 and the smoothing capacitor 5 are housed in a chamber located below the noise filter 7 inside the casing 12. The first busbar portion 151 is housed in a chamber located above the relay busbar 153 inside the casing 12.

In the power converter 4 of the third embodiment, the first chamber 121 is positioned below the second chamber 122. The through busbar portion 152 penetrates the partition wall 12c in the up-down direction, extending across both the first chamber and the second chamber at one location inside the casing 12. According to the third embodiment, by configuring the chambers inside the casing in a vertically stacked two-layer structure, it is possible to provide the power converter that reduces the horizontal length of the casing.

### Other Embodiments

The power converter only needs to be configured such that at least the first chamber 121 and the second chamber 122 are provided within the casing 12. Accordingly, the power converter may be configured to have one or more additional chambers inside the casing 12, in addition to the first chamber 121 and the second chamber 122.

The power converter may also be configured without including the terminal unit 13. An example of a configuration in such a case is as follows. A relay busbar 153 is directly connected to one end of a capacitor busbar, which is connected to a capacitor element. The other end of the capacitor busbar is connected to a terminal 90a of the semiconductor device. As another example, a nut 172 may be incorporated into a capacitor case that forms the smoothing capacitor 5, and a first terminal 153a may be configured to connect the terminal 90a and the terminal 5b.

It is also acceptable for the relay busbar 153 to be in thermally transferable contact with the partition wall 12c via an insulating member. This insulating member is a sheet-like material, grease, gel-like object, gap filler, or the like, formed from an insulating material.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. A power converter comprising:
a casing having a first chamber and a second chamber;
a partition wall separating the first chamber from the second chamber;
semiconductor devices disposed in the first chamber and forming a power conversion circuit;
a smoothing capacitor disposed in the first chamber and electrically connected to the semiconductor devices;
a noise filter disposed in the second chamber and electrically connected to the smoothing capacitor;
a cooling passage formed in the partition wall and configured to allow cooling water to flow therethrough;
a connecting busbar extending between the first chamber and the second chamber and included in a power path that electrically connects a terminal of the noise filter and terminals of the semiconductor devices;
an input busbar included in an input line that electrically connects a DC power supply and the noise filter; and
an output busbar included in an output line electrically connected to the semiconductor devices, wherein
the input busbar extends from the second chamber to outside the casing,
the output busbar extends from the first chamber to outside the casing, and
the connecting busbar includes a through busbar portion that extends between the first chamber and the second chamber at a location within the casing and penetrates the partition wall.

2. The power converter according to claim 1, wherein
the through busbar portion penetrates the partition wall in a region that is farther from the semiconductor devices than a side surface portion of the smoothing capacitor that is closest to the semiconductor devices, as viewed in plan.

3. The power converter according to claim 2, wherein
the through busbar portion penetrates the partition wall at a location outside an external surface portion of the smoothing capacitor that is positioned on an opposite side from the semiconductor devices, as viewed in plan.

4. The power converter according to claim 1, wherein
the connecting busbar further includes:
a first busbar portion extending in the second chamber toward the through busbar portion along the cooling passage; and
a second busbar portion extending in the first chamber from the through busbar portion toward the semiconductor devices along the cooling passage, wherein
the through busbar portion penetrates the partition wall at a position adjacent to the cooling passage.

5. The power converter according to claim 4, wherein
the first busbar portion is disposed between the smoothing capacitor and the cooling passage and is in contact with the partition wall via an insulator.

6. The power converter according to claim 1, further comprising:
a terminal unit including a resin mold incorporating a relay busbar connected to the terminals of the semiconductor devices, wherein
the relay busbar includes a P-side busbar included in a high potential P line and an N-side busbar included in a low potential N line,
the P-side busbar and the N-side busbar each include:
a busbar terminal coupled to the terminals of the semiconductor devices; and
a pair of extension portions bent from the busbar terminal and incorporated in the resin mold, the extension portions extending toward the partition wall in mutually opposed orientations.

7. The power converter according to claim 6, wherein
the P-side busbar and the N-side busbar each have a contact heat dissipation portion that extends from the busbar terminal toward the partition wall and is in contact with the partition wall via an insulator.

8. The power converter according to claim 1, wherein
the first chamber is positioned above the second chamber in an up-down direction, and
the through busbar portion extends in the up-down direction between the first chamber and the second chamber at a location within the casing and penetrates the partition wall.

9. The power converter according to claim 1, wherein
the second chamber is positioned above the first chamber in an up-down direction, and
the through busbar portion extends in the up-down direction between the first chamber and the second chamber at a location within the casing and penetrates the partition wall.

10. The power converter according to claim 1, wherein
the input busbar and the output busbar extend outside the casing from a common side wall of the casing.

11. A power converter comprising:
a casing having a first chamber and a second chamber;
a partition wall separating the first chamber from the second chamber;
semiconductor devices disposed in the first chamber and forming a power conversion circuit;
a smoothing capacitor disposed in the first chamber and electrically connected to the semiconductor devices;
a noise filter disposed in the second chamber and electrically connected to the smoothing capacitor;
a cooling passage formed in the partition wall and configured to allow cooling water to flow therethrough;
a connecting busbar extending between the first chamber and the second chamber and included in a power path that electrically connects a terminal of the noise filter and terminals of the semiconductor devices; and
a terminal unit including a resin mold incorporating a relay busbar connected to the terminals of the semiconductor devices, wherein
the connecting busbar includes a through busbar portion that extends between the first chamber and the second chamber at a location within the casing and penetrates the partition wall,
the relay busbar includes a P-side busbar included in a high potential P line and an N-side busbar included in a low potential N line, and
the P-side busbar and the N-side busbar each include:
a busbar terminal coupled to the terminals of the semiconductor devices; and
a pair of extension portions that are bent from the busbar terminal and incorporated in the resin mold, the extension portions extending in mutually opposed directions toward the partition wall.
